(19) United States
(12) Patent Application Publication
(10) Pub. No.: US 2015/0207488 A1
(43) Pub. Date: Jul. 23, 2015

(54) VoIP PHONE SPLITTING DEVICE HAVING MoCA BLOCK FUNCTION

(71) Applicant: LANTEK ELECTRONICS INC., New Taipei City (TW)

(72) Inventor: Shan-Jui LU, New Taipei City (TW)

(73) Assignee: LANTEK ELECTRONICS INC., New Taipei City (TW)

(21) Appl. No.: 14/289,985

(22) Filed: May 29, 2014

(30) Foreign Application Priority Data
Jan. 23, 2014 (TW) 103201451

(51) Int. Cl. H03H 7/46; H01P 1/22; H03H 7/01

(52) U.S. Cl. CPC H03H 7/46; H03H 7/0115; H01P 1/22

(57) ABSTRACT

The present invention relates to a VoIP phone splitting device having MoCA block function, which includes: a low-pass filtering unit used for inputting a RF signal; a first-stage splitter, a first output end thereof is coupled to an output for attenuating the RF signal to a first value so as to be outputted; a second-stage splitter, an input end thereof is coupled to a second output end of the first-stage splitter for attenuating the RF signal to a second value so as to be outputted; and at least a third-stage splitter, an input end thereof is coupled to an output end of the second-stage splitter for attenuating the RF signal to a third value so as to be outputted to at least a user-end connector.

### BACKGROUND OF THE INVENTION

1. Field of the Invention

The present invention relates to a tap, especially to a VoIP phone splitting device having MoCA block function.

2. Description of Related Art

At present, the cable TV system used in a residence allows a user to use a cable modem or a set top box for being coupled to the cable of a cable TV through a tap, a splitter or a house amplifier for downloading image signals (the frequency thereof is 54 MHz˜1,000 MHz) or uploading data (the frequency thereof is 5 MHz˜42 Mhz) to a mainframe of the cable TV system.

The Multimedia over Coaxial Alliance (MoCA) protocol is a newly-established protocol which allows media audio or video to be transmitted in a coaxial cable of the cable TV, and the communicating frequency range is 1,125 MHz to 1,675 MHz.

However, the conventional tap can only be used for the RF signal having a frequency range of 5 MHz˜1,002 MHz, when being applied in a MoCA system, the RF signal having a frequency range of 1,125 MHz˜1,675 MHz and used between users may be coupled to the input end of the main branch trunk, thereby generating the interference between the RF signals having two frequency ranges and causing the cable TV having poorer quality.

In view of the disadvantages existed in the conventional tap, the present invention provides a VoIP phone splitting device having MoCA block function for improving the above-mentioned disadvantages.

### SUMMARY OF THE INVENTION

One primary objective of the present invention is to provide a VoIP phone splitting device having MoCA block function, which includes a low-pass filtering unit capable of effectively filtering the RF signal having the frequency range of 1,125 MHz-1,675 MHz thereby avoiding the interference generated between the RF signal having the frequency range of 1,125 MHz-1,675 MHz and the cable TV RF signal having the frequency range of 5 MHz-1,002 MHz.

Another objective of the present invention is to provide a VoIP phone splitting device having MoCA block function, which includes a first-stage splitter capable of providing at least an output end of the VoIP phone.

For achieving said objectives, the present invention provides a VoIP phone splitting device having MoCA block function, which includes: a low-pass filtering unit, one end thereof is coupled to an input end of a branch trunk for inputting a RF signal and performing a low-pass filtering operation to the RF signal; a first-stage splitter, an input end thereof is coupled to an output end of the low-pass filtering unit, a first output end thereof is coupled to an output end of the branch trunk for attenuating the RF signal to a first value so as to be outputted; a second-stage splitter, an input end thereof is coupled to a second output end of the first-stage splitter for attenuating the RF signal to a second value so as to be outputted; and at least a third-stage splitter, an input end thereof is coupled to an output end of the second-stage splitter for attenuating the RF signal to a third value so as to be outputted to at least a user-end connector.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a block diagram illustrating the VoIP phone splitting device having MoCA block function according to a preferred embodiment of the present invention;

FIG. 2 is a circuit diagram illustrating the low-pass filtering unit according to the present invention;

FIG. 3 is a circuit diagram illustrating the first-stage splitter according to the present invention;

FIG. 4 is a schematic view illustrating the VoIP phone splitting device having MoCA block function further including a printed circuit board according to a preferred embodiment of the present invention; and

FIG. 5 is a schematic view illustrating the VoIP phone splitting device having MoCA block function further including a housing according to a preferred embodiment of the present invention.

### DETAILED DESCRIPTION OF THE PREFERRED EMBODIMENT

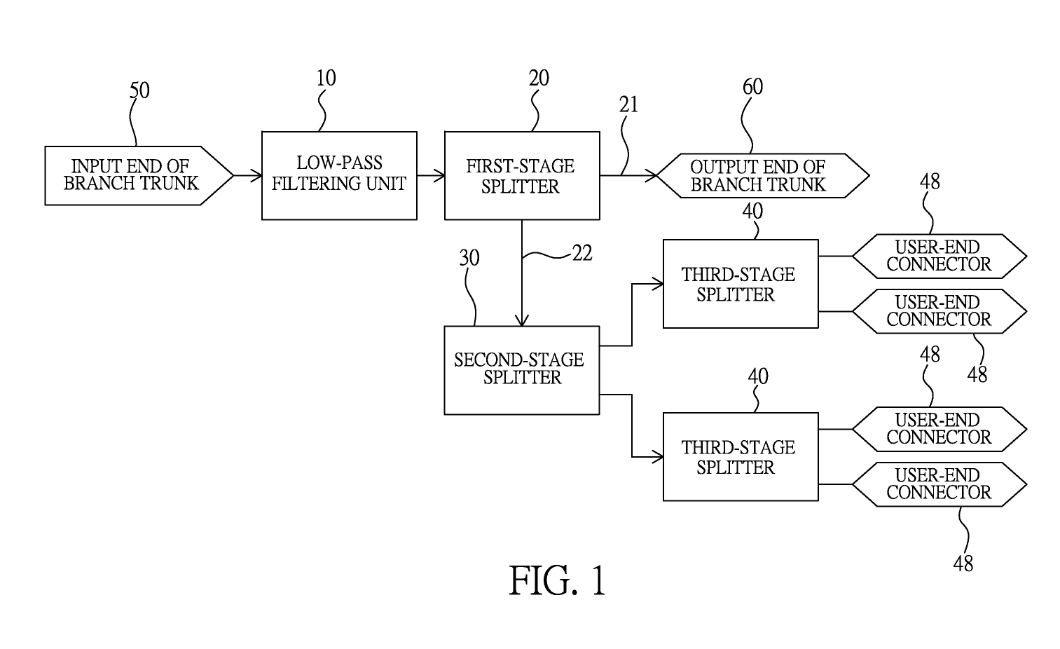

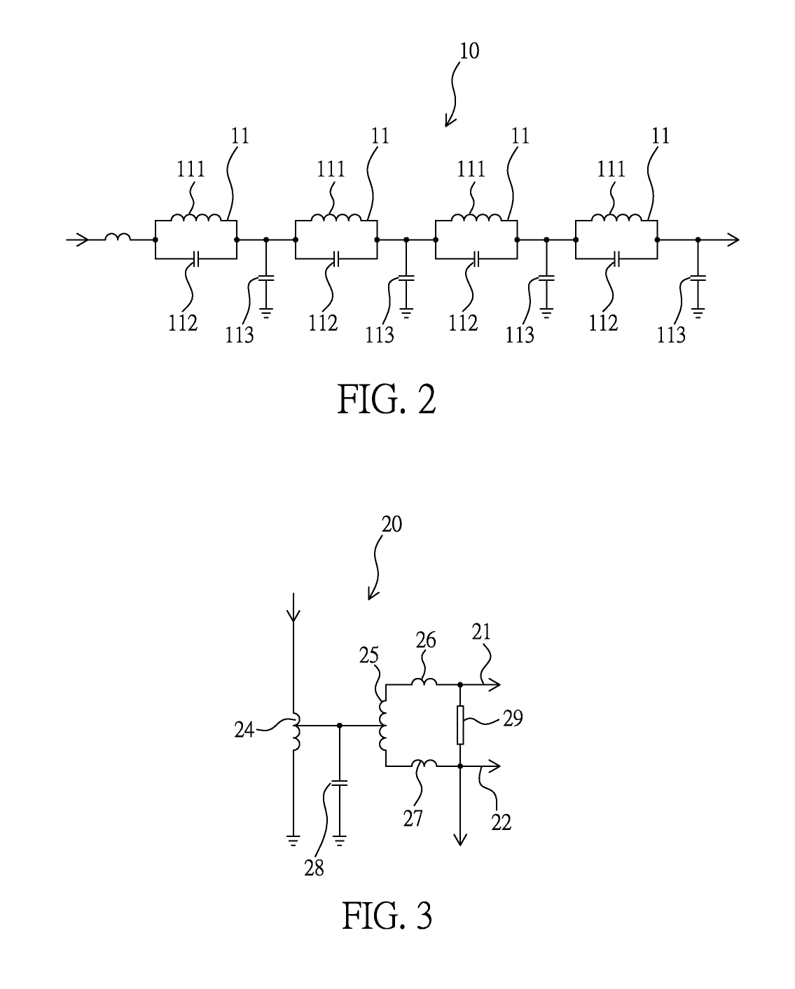

Referring from FIG. 1 to FIG. 3, wherein FIG. 1 is a block diagram illustrating the VoIP phone splitting device having MoCA block function according to a preferred embodiment of the present invention; FIG. 2 is a circuit diagram illustrating the low-pass filtering unit according to the present invention; and FIG. 3 is a circuit diagram illustrating the first-stage splitter according to the present invention.

As shown in figures, the present invention provides a VoIP phone splitting device having MoCA block function, which includes a low-pass filtering unit 10, a first-stage splitter 20, a second-stage splitter 30 and at least a third-stage splitter 40.

One end of the low-pass filtering unit 10 is coupled to an input end of a branch trunk 50 for inputting a RF signal and performing a low-pass filtering operation to the RF signal, wherein the input end of the branch trunk 50 is e.g. but not limited to a coaxial cable connector of a cable TV which is used for inputting a RF signal to a cable (not shown in figures), and the frequency thereof is e.g. but not limited to 5 MHz˜1,002 MHz. The low-pass filtering unit 10 is further installed with at least a low-pass filter 11, the pass frequency range thereof is e.g. but not limited to 5 MHz˜1,002 MHz, and the cutoff frequency range thereof is e.g. but not limited to 1,125 MHz˜1,675 MHz.

An input end of the first-stage splitter 20 is coupled to an output end of the low-pass filtering unit 10, a first output end 21 thereof is coupled to an output end of the branch trunk 60 for attenuating the RF signal to a first value so as to be outputted; wherein, the output end of the branch trunk 60 is e.g. but not limited to an output end of a VoIP phone for outputting a RF signal having a frequency range of 5 MHz˜42 MHz to the cable (not shown in figures), and the first value is e.g. but not limited to 3.5 dB.

An input end of the second-stage splitter 30 is coupled to a second output end 22 of the first-stage splitter 20 for attenuating the RF signal to a second value so as to be outputted; wherein, the second value is e.g. but not limited to 3.5 dB.

An input end of the third-stage splitter 40 is coupled to an output end of the second-stage splitter 30 for attenuating the RF signal to a third value so as to be outputted to at least a user-end connector 48; wherein, the third value is e.g. but not limited to 3.5 dB. The frequency of the RF signal outputted by the user-end connector 48 is 5 MHz˜1,002 MHz and 1,125 MHz˜1,675 MHz, wherein 5 MHz˜1,002 MHz allows the cable TV signals to be uploaded or downloaded. 1,125 MHz˜1,675 MHz allows two user ends to communicate with the MoCA protocol.

As shown in FIG. 2, the low-pass filtering unit 10 is composed of plural low-pass filters 11 defined with multiple stages and connected in series, each of the low-pass filters 11 is composed of at least an inductor 111, a first capacitor 112 being connected in parallel and a second capacitor 113 being grounded. According to this embodiment, the arrangement of four low-pass filters 11 defined with multiple stages and connected in series is adopted as an example for illustration and shall not be the limitation to the scope of the present invention.

As shown in FIG. 3, the first-stage splitter 20 is composed of two coils 24, 25, two inductors 26, 27, a capacitor 28 and a resistor 29, wherein one end of the coil 24 is coupled to the output end of the low-pass filtering unit 10, the other end of the coil 24 is coupled for being grounded; one end of the coil 25 is coupled to one end of the inductor 26, the other end of the coil 25 is coupled to one end of the inductor 27; one end of the capacitor 28 is coupled between the coil 24 and the coil 25, the other end of the capacitor 28 is coupled for being grounded; one end of the resistor 29 is coupled to the other end of the inductor 26, the other end of the resistor 29 is coupled to the other end of the inductor 27, two ends of the resistor 29 are respectively coupled to the output end 60 and the input end of the second-stage splitter 30. Wherein, the second-stage splitter 30 and the third-stage splitter 40 are substantially formed with the same structure as the first-stage splitter 20, thereby no further illustration is provided.

According to the present invention, the operation theory of the VoIP phone splitting device having MoCA block function is as following: when being operated, the cable TV RF signal having a frequency range of 5 MHz˜1,002 MHz and inputted from the input end of the branch trunk 50 is filtered by the low-pass filtering unit 10, and attenuated 3.5 dB by the first-stage splitter 20 for outputting a RF signal having a frequency range of 5 MHz˜42 MHz to the output end 60 of the VoIP phone, and outputting the RF signal having the frequency range of 5 MHz˜1,002 MHz to the input end of the second-stage splitter 30; the RF signal having the frequency range of 5 MHz˜1,002 MHz is further attenuated by the second-stage splitter 30 and the third-stage splitter 40 for reducing the strength by 35 dB (inputted from the input end of the branch trunk 50 to the user end); when the two users are communicating with the MoCA protocol, the RF signal having the frequency range of 1,125 MHz˜1,675 MHz is coupled by the second-stage splitter 30 and the third-stage splitter 40 for being outputted to the second output end 22 of the first-stage splitter 20; after being filtered by the low-pass filtering unit 10, the RF signal having the frequency range of 1,125 MHz˜1,675 MHz is blocked for preventing from entering the input end of the branch trunk 50, so the RF signal having the frequency range of 1,125 MHz˜1,675 MHz can be effectively filtered thereby avoiding the interference generated between the RF signal having the frequency range of 1,125 MHz˜1,675 MHz and the cable TV RF signal having the frequency range of 5 MHz˜1,002 MHz and providing the RF signal having the frequency range of 5 MHz˜42 MHz to the VoIP phone.

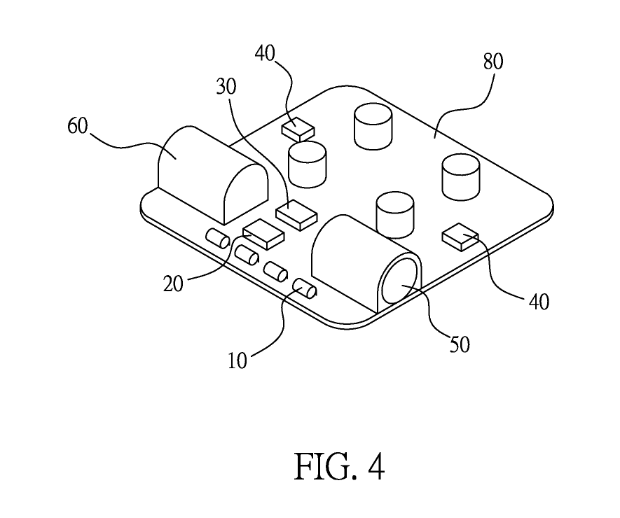

As shown in FIG. 4, the VoIP phone splitting device having MoCA block function further includes a printed circuit board 80 for carrying the low-pass filtering unit 10, the first-stage splitter 20, the second-stage splitter 30 and the at least one third-stage splitter 40.

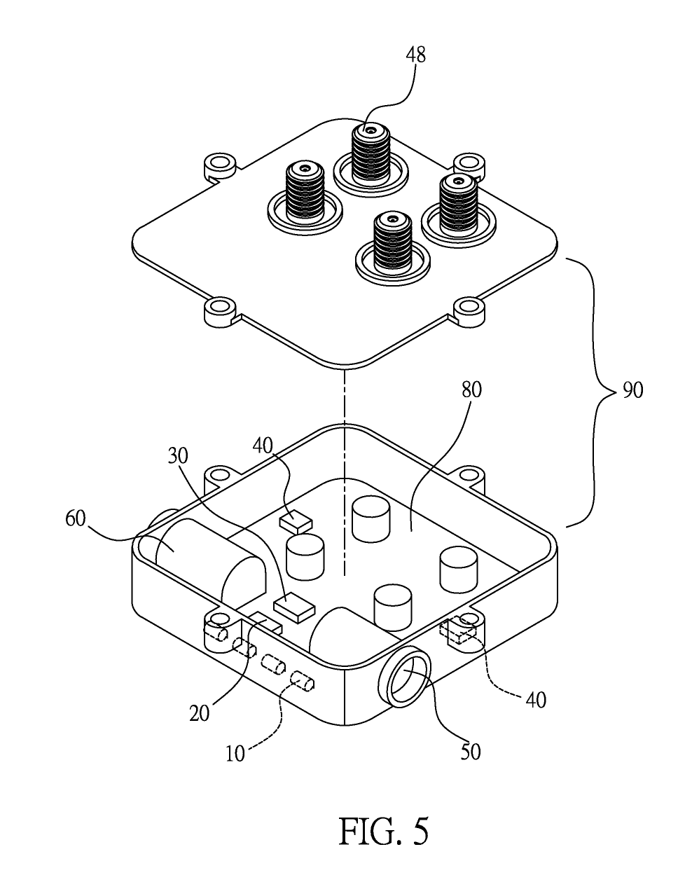

As shown in FIG. 5, the VoIP phone splitting device having MoCA block function further includes a housing 90 for accommodating the printed circuit board 80, the input end of the branch trunk 50, the output end 60 and the user-end connector 48. The housing 90 is e.g. but not limited to be made of a metal material. Accordingly, the VoIP phone splitting device having MoCA block function provided by the present invention is novel and more practical in use comparing to the conventional tap.

Based on what has been disclosed above, advantages achieved by the VoIP phone splitting device having MoCA block function provided by the present invention are as follows: the low-pass filtering unit can be used for effectively filtering the RF signal having the frequency range of 1,125 MHz˜1,675 MHz thereby avoiding the interference generated between the RF signal having the frequency range of 1,125 MHz˜1,675 MHz and the cable TV RF signal having the frequency range of 5 MHz˜1,002 MHz; and the first-stage splitter can be used for providing at least an output end of the VoIP phone. Accordingly, the VoIP phone splitting device having MoCA block function provided by the present invention is novel and more practical in use comparing to the prior art.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific examples of the embodiments disclosed and that modifications and other embodiments are intended to be included within the scope of the appended claims. Although specific terms are employed herein, they are used in a generic and descriptive sense only and not for purposes of limitation.

What is claimed is:

1. A VoIP phone splitting device having MoCA block function, including:
a low-pass filtering unit, one end thereof being coupled to an input end of a branch trunk for inputting a RF signal and performing a low-pass filtering operation to said RF signal;
a first-stage splitter, an input end thereof being coupled to an output end of said low-pass filtering unit, a first output end thereof being coupled to an output end of said branch trunk for attenuating said RF signal to a first value so as to be outputted;
a second-stage splitter, an input end thereof being coupled to a second output end of said first-stage splitter for attenuating the RF signal to a second value so as to be outputted; and
at least a third-stage splitter, an input end thereof being coupled to an output end of said second-stage splitter for attenuating said RF signal to a third value so as to be outputted to at least a user-end connector.

2. The VoIP phone splitting device having MoCA block function as claimed in claim 1, wherein the frequency of said RF signal is 5 MHz˜1,002 MHz.

3. The VoIP phone splitting device having MoCA block function as claimed in claim 1, wherein said low-pass filtering unit is further installed with at least a low-pass filter, the pass frequency range thereof is 5 MHz˜1,002 MHz, and the cutoff frequency range thereof is 1,125 MHz˜1,675 MHz.

4. The VoIP phone splitting device having MoCA block function as claimed in claim 3, wherein said low-pass filtering unit is composed of plural low-pass filters defined with multiple stages and connected in series, each of said low-pass filters is composed of at least an inductor, a first capacitor being connected in parallel and a second capacitor being grounded.

5. The VoIP phone splitting device having MoCA block function as claimed in claim 1, wherein said first-stage splitter is composed of two coils, two inductors, a capacitor and a resistor, and said first value is 3.5 dB.

6. The VoIP phone splitting device having MoCA block function as claimed in claim 1, wherein said second-stage splitter is composed of two coils, two inductors, a capacitor and a resistor, and said second value is 3.5 dB.

7. The VoIP phone splitting device having MoCA block function as claimed in claim 1, wherein said third-stage splitter is composed of two coils, two inductors, a capacitor and a resistor, and said third value is 3.5 dB

8. The VoIP phone splitting device having MoCA block function as claimed in claim 1, wherein the frequency of said RF signal outputted by said user-end connector is 5 MHz˜1,002 MHz and 1,125 MHz˜1,675 MHz, wherein 5 MHz˜1,002 MHz allows the cable TV signals to be uploaded or downloaded. 1,125 MHz˜1,675 MHz allows two user ends to communicate with the MoCA protocol.

9. The VoIP phone splitting device having MoCA block function as claimed in claim 1, wherein said output end of said branch trunk is an output end of the VoIP phone.
